(19) United States
(12) Patent Application Publication
(10) Pub. No.: US 2009/0039431 A1
(43) Pub. Date: Feb. 12, 2009

(54) SEMICONDUCTOR DEVICE

(76) Inventor: Hiroaki Takasu, Chiba-shi (JP)

Correspondence Address: BRINKS HOFER GILSON & LIONE, P.O. BOX 10395, CHICAGO, IL, 60610, US

(21) Appl. No.: 12/184,585

(22) Filed: Aug. 1, 2008

(30) Foreign Application Priority Data
Aug. 6, 2007 (JP) JP2007-204359
Aug. 6, 2007 (JP) JP2007-204360
Jul. 4, 2008 (JP) JP2008-175655

(51) Int. Cl. H01L 27/088

(52) U.S. Cl. 257/360; 257/E27.06

(57) ABSTRACT

Provided is a semiconductor device, including: an N-type MOS transistor for an internal element and a P-type MOS transistor for an internal element both provided in an internal circuit region; and an N-type MOS transistor for ESD protection provided between an external connection terminal and the internal circuit region, in which a gate electrode of the N-type MOS transistor for ESD protection is formed of P-type polysilicon.

### RELATED APPLICATIONS

This application claims priority under 35 U.S.C. §119 to Japanese Patent Application Nos. JP2007-204359 filed on Aug. 6, 2007, JP2007-204360 filed on Aug. 6, 2007, and JP2008-175655 filed on Jul. 4, 2008, the entire contents of which are hereby incorporated by reference.

### BACKGROUND OF THE INVENTION

1. Field of the Invention

The present invention relates to a semiconductor device having MOS transistors in which an N-type MOS transistor is used as an ESD protection element.

2. Description of the Related Art

In a semiconductor device having MOS transistors, an N-type MOS transistor whose gate potential is fixed to the ground potential (Vss) to hold in an off state is known as an off transistor, and used as an ESD protection element for preventing breakdown of an internal circuit due to static electricity from a pad for external connection.

As illustrated in FIG. 6, a gate electrode 521 of an off transistor 721 is formed of the same N-type polysilicon film as an N-type MOS transistor 701 and a P-type MOS transistor 711 of internal elements located in an internal circuit region. Further, even in a semiconductor device with a CMOS circuit having a homo-polar gate structure where a gate electrode of the N-type MOS transistor 701 is formed of an N-type polysilicon film and a gate electrode of the P-type MOS transistor 711 is formed of a P-type polysilicon film, the gate electrode 521 of the off transistor is formed of the same N-type polysilicon film as an N-type MOS transistor for an internal element located in an internal circuit region.

Different from MOS transistors forming an internal circuit such as a logic circuit, the off transistor must flow all of a large amount of current caused by static electricity all at once, and thus, the transistor width (W) is often set as large as several hundred microns.

Though the gate potential of the off transistor is fixed to the Vss to hold the off transistor in an off state, a subthreshold current is generated to some extent similarly to the case of an N-type MOS transistor of an internal circuit, since the threshold voltage is less than 1 V. As described above, because the width W of the off transistor is large, an off-state leakage current during standby is large accordingly, and thus, there is a problem that current consumption during standby of the whole IC having the off transistor mounted thereon increases.

As a countermeasure thereagainst, a plurality of transistors are disposed between a power supply line (Vdd) and the ground line (Vss) such that the ESD protection element is brought to a complete off state (see, for example, Japanese Patent Application Laid-Open No. 2002-231886).

However, if the W is made small in order to lower the off-state leakage current of the off transistor, the off transistor can not satisfactorily perform the function of protection. Further, in a semiconductor device where a plurality of transistors are disposed between the power supply line (Vdd) and the ground line (Vss) to maintain a complete off state as described in Japanese Patent Application Laid-Open No. 2002-231886, there is a problem that the occupation area of the plurality of transistors increases, leading to a rise in cost of the semiconductor device.

### SUMMARY OF THE INVENTION

In order to solve the above-mentioned problems, a semiconductor device according to the present invention includes the following structures.

A semiconductor device includes: at least an N-type MOS transistor for an internal element provided in an internal circuit region; and an N-type MOS transistor for ESD protection provided between an external connection terminal and the internal circuit region, the N-type MOS transistor for ESD protection serving to protect the N-type MOS transistor for the internal element and other internal elements from breakdown due to ESD. In the semiconductor device, a threshold voltage of the N-type MOS transistor for ESD protection is set to be higher than a threshold voltage of the N-type MOS transistor for the internal element.

A gate electrode of the N-type MOS transistor for ESD protection is formed of P-type polysilicon.

The internal circuit region includes the N-type MOS transistor for the internal element and a P-type MOS transistor for an internal element. A gate electrode of the N-type MOS transistor for the internal element and a gate electrode of the P-type MOS transistor for the internal element are formed of N-type polysilicon.

The internal circuit region includes the N-type MOS transistor for the internal element and a P-type MOS transistor for an internal element. A gate electrode of the N-type MOS transistor for the internal element is formed of N-type polysilicon whereas a gate electrode of the P-type MOS transistor for the internal element is formed of P-type polysilicon.

A concentration of a P-type impurity in a channel region of the N-type MOS transistor for ESD protection is set to be higher than a concentration of a P-type impurity in a channel region of the N-type MOS transistor for the internal element.

The P-type impurity in the channel region of the N-type MOS transistor for ESD protection is formed of a P-type impurity for adjusting a channel concentration of other MOS transistors formed in the internal circuit region, in addition to one of an impurity of a P-type substrate and an impurity of a P-type well region, and a P-type impurity for adjusting a channel concentration of the N-type MOS transistor for the internal element.

By using the P-type polysilicon for the gate electrode of the N-type MOS transistor for ESD protection, because of the difference in work function of the gate electrode material, compared with a conventional case where N-type polysilicon is used for the gate electrode, a higher threshold voltage can be obtained, and thus, there can be obtained a semiconductor device having an N-type MOS transistor for ESD protection, which can suppress the off-state leakage current while satisfactorily performing the function of ESD protection, without increasing the process steps and the occupation area.

### BRIEF DESCRIPTION OF THE DRAWINGS

In the accompanying drawings:

FIG. 1 is a schematic sectional view illustrating an N-type MOS transistor for ESD protection, an N-type MOS transistor for an internal element, and a P-type MOS transistor for an internal element of a semiconductor device according to a first embodiment of the present invention;

FIG. 2 is a schematic sectional view illustrating an N-type MOS transistor for ESD protection, an N-type MOS transistor for an internal element, and a P-type MOS transistor for an internal element of a semiconductor device according to a second embodiment of the present invention;

FIG. 3 is a schematic sectional view illustrating an N-type MOS transistor for ESD protection, an N-type MOS transistor for an internal element, and a P-type MOS transistor for an internal element of a semiconductor device according to a third embodiment of the present invention;

FIG. 4 is a schematic sectional view illustrating an N-type MOS transistor for ESD protection, an N-type MOS transistor for an internal element, and a P-type MOS transistor for an internal element of a semiconductor device according to a fourth embodiment of the present invention;

FIG. 5 is a schematic sectional view illustrating an N-type MOS transistor for ESD protection, an N-type MOS transistor for an internal element, and a P-type MOS transistor for an internal element of a semiconductor device according to a fifth embodiment of the present invention; and

FIG. 6 is a schematic sectional view illustrating an N-type MOS transistor for ESD protection, an N-type MOS transistor for an internal element, and a P-type MOS transistor for an internal element of a conventional semiconductor device.

### DETAILED DESCRIPTION OF THE PREFERRED EMBODIMENTS

### FIRST EMBODIMENT

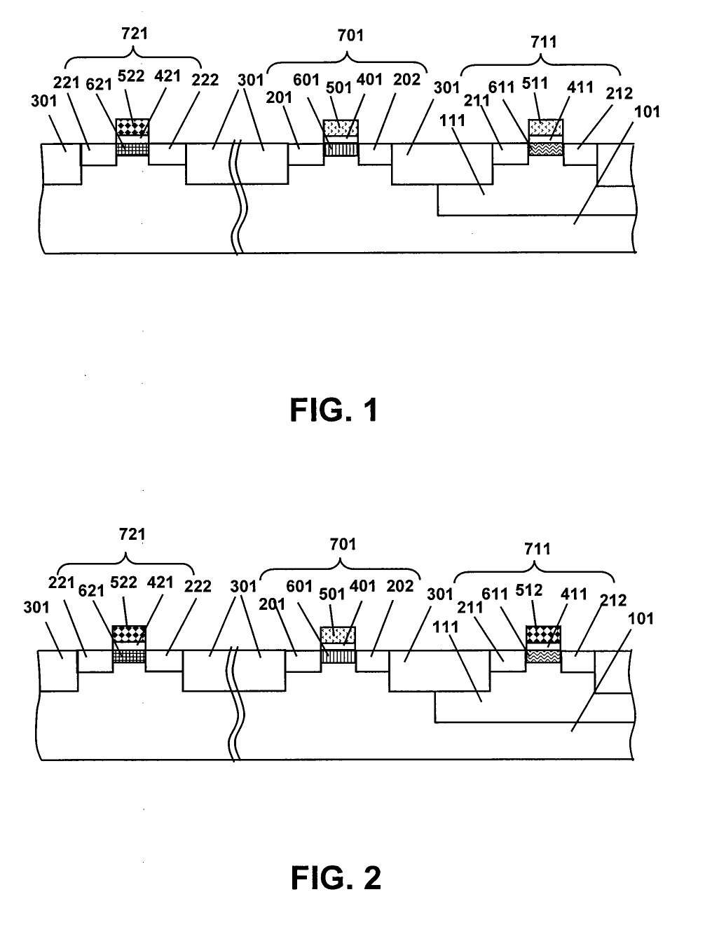

FIG. 1 is a schematic sectional view illustrating an N-type MOS transistor for ESD protection, an N-type MOS transistor for an internal element, and a P-type MOS transistor for an internal element of a semiconductor device according to a first embodiment of the present invention.

First, an N-type MOS transistor 721 for ESD protection is described.

A pair of a source region 221 of the N-type MOS transistor for ESD protection and a drain region 222 of the N-type MOS transistor for ESD protection which are formed of N-type heavily doped impurity regions are formed on a P-type silicon substrate 101 as a semiconductor substrate of a first conductivity type. The source region 221 and the drain region 222 are electrically isolated from other elements by an element isolation region 301 formed therebetween by shallow trench isolation or LOCOS.

A channel region 621 of the N-type MOS transistor for ESD protection is formed between the source region 221 of the N-type MOS transistor for ESD protection and the drain region 222 of the N-type MOS transistor for ESD protection. A P-type gate electrode 522 of the N-type MOS transistor for ESD protection is formed above the channel region 621 via a gate insulating film 421. The P-type gate electrode 522 is formed of a P-type polysilicon film and the gate insulating film 421 is formed of a silicon oxide film or the like. It is to be noted that the source region 221 is electrically connected so as to have the same ground potential (Vss) as that of the P-type gate electrode 522 of the N-type MOS transistor for ESD protection (not shown), which makes the N-type MOS transistor 721 for ESD protection maintain an off state, which is a state of a so-called off transistor. Further, the drain region 222 is connected to an external connection terminal.

It is to be noted that, for the sake of simplicity, in the example of FIG. 1, only the N-type MOS transistor 721 for ESD protection which has the pair of the source region 221 of the N-type MOS transistor for ESD protection and the drain region 222 of the N-type MOS transistor for ESD protection which are formed of N-type heavily doped impurity regions is illustrated. However, since an actual N-type MOS transistor for ESD protection requires a large transistor width in order to flow a large amount of current due to static electricity, an actual N-type MOS transistor for ESD protection is often formed to have a number of source and drain regions.

Next, an N-type MOS transistor 701 of an internal element and a P-type MOS transistor 711 of an internal element are described.

First, with regard to the N-type MOS transistor 701 of an internal element, a pair of a source region 201 of the N-type MOS transistor for an internal element and a drain region 202 of the N-type MOS transistor for an internal element which are formed of N-type heavily doped impurity regions are formed on the P-type silicon substrate 101 as the semiconductor substrate of the first conductivity type. The source region 201 and the drain region 202 are electrically isolated from other elements by the element isolation region 301 formed therebetween by shallow trench isolation or LOCOS.

A channel region 601 of the N-type MOS transistor for an internal element is formed between the source region 201 of the N-type MOS transistor for an internal element and the drain region 202 of the N-type MOS transistor for an internal element. An N-type gate electrode 501 of the N-type MOS transistor for an internal element is formed above the channel region 601 via a gate insulating film 401. The N-type gate electrode 501 is formed of an N-type polysilicon film and the gate insulating film 401 is formed of a silicon oxide film or the like.

Next, with regard to the P-type MOS transistor 711 of an internal element, a pair of a source region 211 of the P-type MOS transistor for an internal element and a drain region 212 of the P-type MOS transistor for an internal element which are formed of P-type heavily doped impurity regions are formed on an N-well region 111 provided on the P-type silicon substrate 101 as the semiconductor substrate of the first conductivity type. The source region 211 and the drain region 212 are electrically isolated from other elements by the element isolation region 301 formed therebetween by shallow trench isolation or LOCOS.

A channel region 611 of the P-type MOS transistor for an internal element is formed between the source region 211 of the P-type MOS transistor for an internal element and the drain region 212 of the P-type MOS transistor for an internal element. An N-type gate electrode 511 of the P-type MOS transistor for an internal element is formed above the channel region 611 via a gate insulating film 411. The N-type gate electrode 511 is formed of an N-type polysilicon film and the gate insulating film 411 is formed of a silicon oxide film or the like.

Next, characteristics of the present invention are described comparing the N-type MOS transistor 721 for ESD protection, the N-type MOS transistor 701 of an internal element, and the P-type MOS transistor 711 of an internal element.

In the N-type MOS transistor 721 for ESD protection, the P-type gate electrode 522 of the N-type MOS transistor for ESD protection is formed of P-type polysilicon, and thus, because of the difference in work function between the P-type polysilicon and the P-type silicon substrate 101 forming the channel region 621 of the N-type MOS transistor for ESD protection, a higher inversion voltage is necessary compared with the inversion voltage of the N-type MOS transistor 701 for an internal element.

In other words, the N-type MOS transistor 721 for ESD protection has a higher threshold voltage than that of the N-type MOS transistor 701 for an internal element, and thus, the off-state leakage current in a case where the gate potential is fixed to 0 V (Vss) can be suppressed to a low level.

The N-type MOS transistor 721 for ESD protection is different from MOS transistors forming an internal circuit such as a logic circuit including the N-type MOS transistor 701 for an internal element, and must flow all of a large amount of current due to static electricity all at once, and thus, the transistor width (W) is set as large as several hundred microns. Accordingly, suppression of the off-state leakage current of the N-type MOS transistor 721 for ESD protection is highly effective in decreasing current consumption during standby of the whole semiconductor device having the N-type MOS transistor 721 for ESD protection mounted thereon.

According to the present invention, because the P-type gate electrode 522 of the N-type MOS transistor for ESD protection is formed of P-type polysilicon, the N-type MOS transistor 721 for ESD protection has a higher threshold voltage than that of the N-type MOS transistor 701 of an internal element having the gate electrode formed of N-type polysilicon, and thus, the off-state leakage current in the case where the gate potential is fixed to 0 V (Vss) can be effectively made small. This makes it possible to decrease current consumption during standby of the whole semiconductor device having the N-type MOS transistor 721 for ESD protection with a large W mounted thereon.

### SECOND EMBODIMENT

FIG. 2 is a schematic sectional view illustrating an N-type MOS transistor for ESD protection, an N-type MOS transistor for an internal element, and a P-type MOS transistor for an internal element of a semiconductor device according to a second embodiment of the present invention.

This embodiment is different from the first embodiment illustrated in FIG. 1 in that the gate electrode of the P-type MOS transistor 711 of an internal element is formed of a P-type polysilicon film. In FIG. 2, this is illustrated as a P-type gate electrode 512 of a P-type MOS transistor for an internal element.

In the example illustrated in FIG. 2, the gate electrode of the N-type MOS transistor 701 of an internal element is formed of an N-type polysilicon film, and the gate electrode of the P-type MOS transistor 711 of an internal element is formed of a P-type polysilicon film. This is a structure generally called a homopolar gate transistor. In particular, this is often used as a technique to make possible low voltage operation of the semiconductor device by forming a channel of a P-type MOS transistor on the side of a silicon substrate surface and making small the leakage current.

According to the present invention, the P-type gate electrode 512 of the P-type MOS transistor for an internal element and the P-type gate electrode 522 of the N-type MOS transistor for ESD protection are formed of the same P-type polysilicon film.

This makes it possible to obtain a semiconductor device having homopolar gates, which makes small the off-state leakage current described in the first embodiment while satisfactorily performing the function of protection against static electricity required to the N-type MOS transistor 721 for ESD protection, and is capable of operating at low voltage without increasing the process steps and the occupation area.

With regard to other members, like numerals are used to designate like or identical members illustrated in FIG. 1, and description thereof is omitted.

### THIRD EMBODIMENT

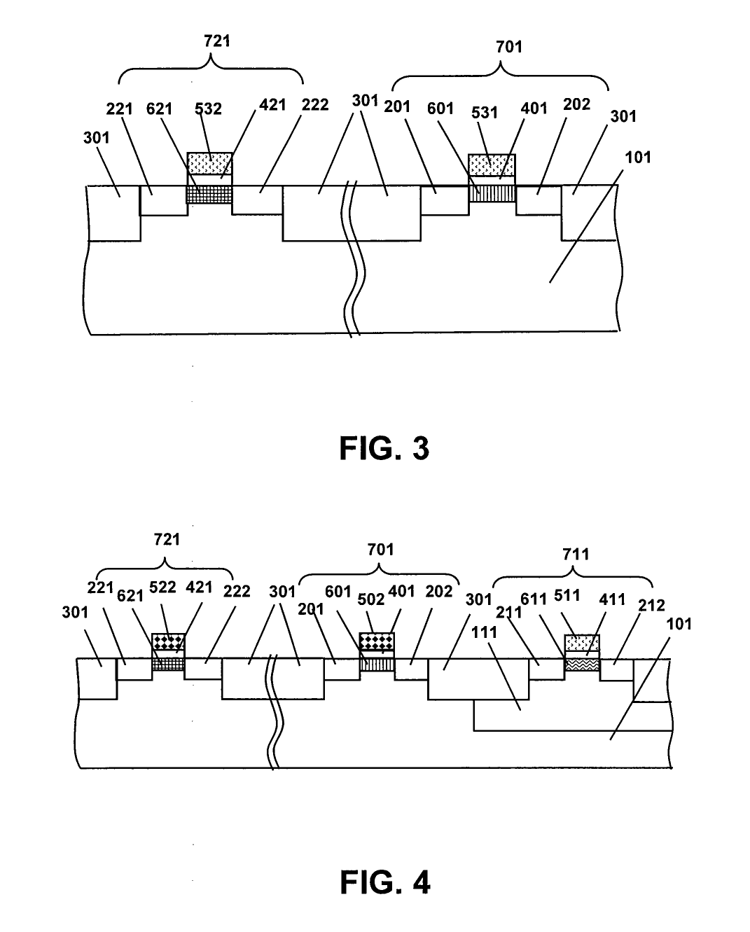

FIG. 3 is a schematic sectional view illustrating an N-type MOS transistor for ESD protection, an N-type MOS transistor for an internal element, and a P-type MOS transistor for an internal element of a semiconductor device according to a third embodiment of the present invention.

First, the N-type MOS transistor 721 for ESD protection is described.

The pair of the source region 221 and the drain region 222 which is formed of N-type heavily doped impurity regions is formed on the P-type silicon substrate 101 as the semiconductor substrate of the first conductivity type. The source region 221 and the drain region 222 are electrically isolated from other elements by the element isolation region 301 formed therebetween by shallow trench isolation or LOCOS.

The channel region 621 of the N-type MOS transistor 721 for ESD protection is formed between the source region 221 and the drain region 222. A gate electrode 532 formed of a polysilicon film or the like is formed above the channel region 621 via the gate insulating film 421 formed of a silicon oxide film or the like. It is to be noted that the source region 221 is electrically connected so as to have the same ground potential (Vss) as that of the gate electrode 532 (not shown), which makes the N-type MOS transistor 721 for ESD protection maintain an off state, which is the state of the so-called off transistor. Further, the drain region 222 is connected to the external connection terminal.

It is to be noted that, for the sake of simplicity, in the example of FIG. 3, only the N-type MOS transistor for ESD protection which has the pair of the source region 221 and the drain region 222 which are formed of N-type heavily doped impurity regions is illustrated. However, an actual N-type MOS transistor for ESD protection requires a large transistor width in order to flow a large amount of current due to static electricity. Accordingly, an actual N-type MOS transistor for ESD protection is often formed to have a number of source and drain regions.

Next, the N-type MOS transistor 701 of an internal element is described.

The pair of the source region 201 and the drain region 202 which is formed of N-type heavily doped impurity regions is formed on the P-type silicon substrate 101 as the semiconductor substrate of the first conductivity type. The source region 201 and the drain region 202 are electrically isolated from other elements by the element isolation region 301 formed therebetween by shallow trench isolation or LOCOS.

The channel region 601 of the N-type MOS transistor 701 of an internal element is formed between the source region 201 and the drain region 202. A gate electrode 531 formed of a polysilicon film or the like is formed above the channel region 601 via the gate insulating film 401 formed of a silicon oxide film or the like. It is to be noted that, for the sake of simplicity, only the N-type MOS transistor 701 of an internal element is illustrated. However, in an actual IC, a number of elements, such as a P-type MOS transistor, forming a semiconductor circuit are formed.

Next, characteristics of the present invention are described comparing the N-type MOS transistor 721 for ESD protection and the N-type MOS transistor 701 of an internal element.

The concentration of a P-type impurity of the channel region 621 of the N-type MOS transistor 721 for ESD protection is set to be higher than the concentration of a P-type impurity of the channel region 601 of the N-type MOS transistor 701 of an internal element, whereby the threshold voltage of the N-type MOS transistor 721 for ESD protection is set to be higher than that of the N-type MOS transistor 701 of an internal element.

The N-type MOS transistor 721 for ESD protection is different from MOS transistors forming an internal circuit such as a logic circuit including the N-type MOS transistor 701 of an internal element, and requires to flow to the end at a time a large amount of current due to static electricity, and thus, the transistor width (W) is set to be as large as several hundred microns. Here, because the threshold voltage of the N-type MOS transistor 721 for ESD protection is set to be higher than that of the N-type MOS transistor 701 of an internal element, the off-state leakage current during standby can be made small, and current consumption during standby of the whole IC having the N-type MOS transistor 721 for ESD protection with a large W mounted thereon can be decreased.

Here, the P-type impurity of the channel region 621 of the N-type MOS transistor 721 for ESD protection is formed of the P-type impurity of the P-type silicon substrate 101 (or, when a P-type well region is formed and the N-type MOS transistor 721 for ESD protection is formed therein, the P-type impurity of the P-type well region (not shown)), the P-type impurity for adjusting the concentration of the channel region 601 of the N-type MOS transistor 701 of an internal element, and the P-type impurity for adjusting the channel concentration of other MOS transistors formed in an internal circuit region (for example, P-type MOS transistor, depletion N-type transistor, or N-type or P-type MOS transistor having different threshold value). In other words, a larger amount of P-type impurity is introduced in the channel region 621 of the N-type MOS transistor 721 for ESD protection compared with that in the channel region 601 of the N-type MOS transistor 701 of an internal element.

This makes it possible to set the threshold voltage of the N-type MOS transistor 721 for ESD protection to be higher than the threshold voltage of the N-type MOS transistor 701 of an internal element, and thus, the subthreshold current of the N-type MOS transistor 721 for ESD protection is made small, and the leakage current can be made small.

In this way, there can be obtained a semiconductor device having an N-type MOS transistor for ESD protection, which makes small the off-state leakage current while satisfactorily performing the ESD protection function, without increasing the process steps and the occupation area.

According to this embodiment, the threshold voltage is changed making use of the difference in concentration of the channel regions of the MOS transistors, which may be implemented in combination with the first embodiment and the second embodiment. In a fourth embodiment and a fifth embodiment described below, the threshold voltage is also changed making use of the difference in concentration of the channel regions of the MOS transistors.

### FOURTH EMBODIMENT

FIG. 4 is a schematic sectional view illustrating an N-type MOS transistor for ESD protection, an N-type MOS transistor for an internal element, and a P-type MOS transistor for an internal element of a semiconductor device according to the fourth embodiment of the present invention.

The concentration of a P-type impurity of the channel region 621 of the N-type MOS transistor 721 for ESD protection is set to be higher than the concentration of a P-type impurity of the channel region 601 of the N-type MOS transistor 701 of an internal element, whereby the threshold voltage of the N-type MOS transistor 721 for ESD protection is set to be higher than that of the N-type MOS transistor 701 of an internal element. Further, gate electrodes of the N-type MOS transistor 721 for ESD protection and of the N-type MOS transistor 701 of an internal element are formed of P-type polysilicon while the gate electrode of a P-type MOS transistor 711 of an internal element is formed of N-type polysilicon. This is opposite to the case of the homopolar gate transistors illustrated in FIG. 2. This is for the purpose of improving the driving force (current driving ability) of the transistors by forming both of the channels of the N-type MOS transistors and the channel of the P-type MOS transistor away from the side of the silicon substrate surface, avoiding the inconvenience of the crystallinity of the silicon surface, and forming the channels in an internal region where less defects are caused.

According to the present invention, a P-type gate electrode 502 of the N-type MOS transistor for an internal element and the P-type gate electrode 522 of the N-type MOS transistor for ESD protection are formed of the same P-type polysilicon film.

This makes it possible to obtain a semiconductor device with high current driving ability, which makes small the off-state leakage current described in the third embodiment while satisfactorily performing the function of protection against static electricity required to the N-type MOS transistor 721 for ESD protection, without increasing the process steps and the occupation area.

With regard to other members, like numerals are used to designate like or identical members illustrated in FIG. 1, and description thereof is omitted.

### FIFTH EMBODIMENT

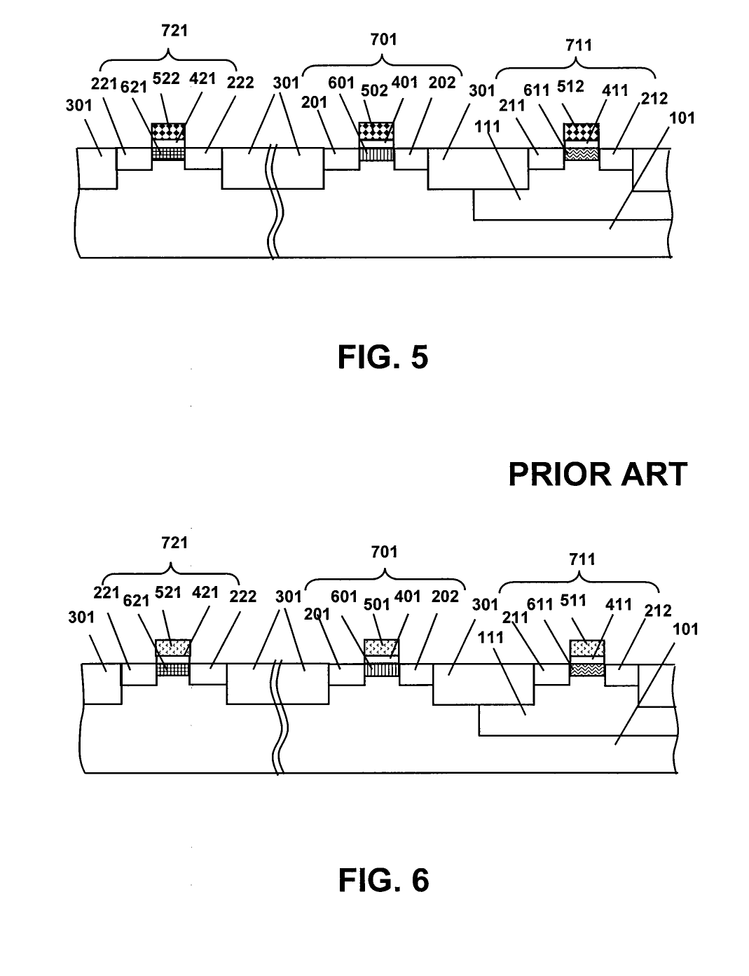

FIG. 5 is a schematic sectional view illustrating an N-type MOS transistor for ESD protection, an N-type MOS transistor for an internal element, and a P-type MOS transistor for an internal element of a semiconductor device according to the fifth embodiment of the present invention.

The concentration of a P-type impurity of a channel region 621 of an N-type MOS transistor 721 for ESD protection is set to be higher than the concentration of a P-type impurity of a channel region 601 of an N-type MOS transistor 701 of an internal element, whereby the threshold voltage of the N-type MOS transistor 721 for ESD protection is set to be higher than that of the N-type MOS transistor 701 of an internal element. Further, gate electrodes of the N-type MOS transistor 721 for ESD protection and of the MOS transistors 701 and 711 of an internal element are formed of P-type polysilicon. This is for the purpose of improving the driving force (current driving ability) of the transistors by forming the channels of the N-type MOS transistors away from the side of the silicon substrate surface, avoiding the inconvenience of the crystallinity of the silicon surface, and forming the channels in an internal region where less defects are caused. Besides, the channel of the P-type MOS transistor is formed on the side of the silicon substrate surface, and thus, the leakage current can be made small.

According to the present invention, a P-type gate electrode 502 of the N-type MOS transistor for an internal element, a P-type gate electrode 512 of the P-type MOS transistor for an internal element, and a P-type gate electrode 522 of the N-type MOS transistor for ESD protection are formed of the same P-type polysilicon film.

This makes it possible to obtain a semiconductor device which makes small the off-state leakage current described in the first embodiment while satisfactorily performing the function of protection against static electricity required to the N-type MOS transistor 721 for ESD protection, gives high current driving ability to the N-type MOS transistor 701 of the internal element, and makes small the leakage current of the P-type MOS transistor 711 of the internal element, without increasing the process steps and the occupation area.

With regard to other members, like numerals are used to designate like or identical members illustrated in FIG. 1, and description thereof is omitted.

What is claimed is:

1. A semiconductor device, comprising:
at least an N-type MOS transistor for an internal element provided in an internal circuit region; and
an N-type MOS transistor for ESD protection provided between an external connection terminal and the internal circuit region, the N-type MOS transistor for ESD protection serving to protect the N-type MOS transistor for the internal element and other internal elements from breakdown due to ESD,
wherein a threshold voltage of the N-type MOS transistor for ESD protection is set to be higher than a threshold voltage of the N-type MOS transistor for the internal element.

2. A semiconductor device according to claim 1, wherein a gate electrode of the N-type MOS transistor for ESD protection is formed of P-type polysilicon.

3. A semiconductor device according to claim 2, wherein:
the internal circuit region comprises the N-type MOS transistor for the internal element and a P-type MOS transistor for an internal element; and
a gate electrode of the N-type MOS transistor for the internal element and a gate electrode of the P-type MOS transistor for the internal element are formed of N-type polysilicon.

4. A semiconductor device according to claim 2, wherein:
the internal circuit region comprises the N-type MOS transistor for the internal element and a P-type MOS transistor for an internal element; and
a gate electrode of the N-type MOS transistor for the internal element is formed of N-type polysilicon whereas a gate electrode of the P-type MOS transistor for the internal element is formed of P-type polysilicon.

5. A semiconductor device according to claim 1, wherein a concentration of a P-type impurity in a channel region of the N-type MOS transistor for ESD protection is set to be higher than a concentration of a P-type impurity in a channel region of the N-type MOS transistor for the internal element.

6. A semiconductor device according to claim 5, wherein the P-type impurity in the channel region of the N-type MOS transistor for ESD protection is formed of a P-type impurity for adjusting a channel concentration of other MOS transistors formed in the internal circuit region, in addition to one of an impurity of a P-type substrate and an impurity of a P-type well region, and a P-type impurity for adjusting a channel concentration of the N-type MOS transistor for the internal element.
